(19) United States
(12) Patent Application Publication
(10) Pub. No.: US 2026/0247707 A1
(43) Pub. Date: Aug. 20, 2026

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Zhifu LI, Wuhan, Hubei (CN); Guanghui LIU, Wuhan, Hubei (CN); Fei AI, Wuhan, Hubei (CN); Dewei SONG, Wuhan, Hubei (CN); Zhuang LI, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/843,248

(22) PCT Filed: Jun. 29, 2023
(86) PCT No.: PCT/CN2023/104290

§ 371 Date: Aug. 31, 2024

(30) Foreign Application Priority Data
Dec. 8, 2022 (CN) 202211575067.9

(51) Int. Cl. H10D 86/40

(52) U.S. Cl. CPC H10D 86/421; H10D 86/451

(57) ABSTRACT

A display panel and a display device are provided. The display panel includes a substrate and a bump structure. The bump structure includes at least two stacked Ohmic contact layers and at least one insulating layer. One insulating layer is placed between two adjacent Ohmic contact layers. At least part of the semiconductor layer is located on a sidewall of the bump structure. The sidewall includes a first sidewall of the Ohmic contact layer and a second sidewall of the insulating layer arranged on the same side. The semiconductor layer includes at least one channel located on the second sidewall.

### FIELD OF DISCLOSURE

The present application relates to the field of display technology, and particularly to a display panel and a display device.

### DESCRIPTION OF RELATED ART

Integrating circuits such as pixel driving circuits, gate driving circuits, multiplex power circuits, source driving circuits, and timing controllers on a glass substrate (system on glass, SOG) can significantly enhance the integration of display panels, reduce dependency on integrated circuit chips, and thus lower costs. Implementing SOG requires improving the integration, maximum operating frequency, and current density of thin-film transistors in existing display panels. These improvements necessitate thin-film transistors with shorter channel lengths, higher mobility, and smaller volumes.

However, the architecture of thin-film transistors in existing display panels cannot further reduce the occupying area of thin-film transistors, and there is a need to enhance device integration.

### SUMMARY OF INVENTION

Embodiments of the present application provide a display panel and a display device to address the technical issue of large footprint of thin-film transistors in existing display panels.

Accordingly, the present application provides technical solution as follows.

The present application provides a display panel, including a substrate and a bump structure disposed on the substrate, the bump structure comprising at least two Ohmic contact layers stacked and at least one insulating layer, wherein one insulating layer is disposed between each adjacent pair of the Ohmic contact layers; the display panel further includes a semiconductor layer, wherein at least part of the semiconductor layer is located on a sidewall of the bump structure, and the sidewall includes a first sidewall of the Ohmic contact layer and a second sidewall of the insulating layer disposed on a same side; the semiconductor layer includes at least one channel, and the channel is located on the second sidewall.

In the display panel of the present application, the display panel further includes a gate disposed on one side of the semiconductor layer away from the bump structure, wherein an orthographic projection of the gate on the sidewall covers an orthographic projection of the channel on the sidewall.

In the display panel of the present application, the at least two Ohmic contact layers include a first Ohmic contact layer and a second Ohmic contact layer sequentially stacked on the substrate, the at least one insulating layer includes a first insulating layer, and the first insulating layer is located between the first Ohmic contact layer and the second Ohmic contact layer;
the at least one channel includes a first channel, and the first channel is disposed on the second sidewall of the first insulating layer.

In the display panel of the present application, the at least two Ohmic contact layers further include a third Ohmic contact layer disposed on the second Ohmic contact layer, the at least one insulating layer further includes a second insulating layer, and the second insulating layer is located between the second Ohmic contact layer and the third Ohmic contact layer;
the at least one channel further includes a second channel, and the second channel is located on the second sidewall of the second insulating layer.

In the display panel of the present application, the display panel further includes:
a gate insulation layer disposed between the gate and the semiconductor layer;
an interlayer dielectric layer disposed on one side of the gate away from the substrate, the interlayer dielectric layer covering the gate and the gate insulation layer;
a source-drain metal layer disposed on one side of the interlayer dielectric layer away from the substrate, the source-drain metal layer comprising a first drain, a source, and a second drain; and
a first contact hole, a second contact hole, and a third contact hole, penetrating through the interlayer dielectric layer and the gate insulation layer;
wherein the source is connected to the second Ohmic contact layer through the first contact hole, the first drain is connected to the first Ohmic contact layer through the second contact hole, and the second drain is connected to the third Ohmic contact layer through the third contact hole.

In the display panel of the present application, the first Ohmic contact layer, the second Ohmic contact layer, and the third Ohmic contact layer are arranged in a stepped configuration;
the first Ohmic contact layer includes a first protruding part, and an orthographic projection of the second Ohmic contact layer on the substrate avoids overlapping with an orthographic projection of the first protruding part on the substrate; the second Ohmic contact layer includes a second protruding part, and an orthographic projection of the third Ohmic contact layer on the substrate avoids overlapping with an orthographic projection of the second protruding part on the substrate.

In the display panel of the present application, the first drain and the second drain are located on two opposite sides of the source, respectively.

In the display panel of the present application, orthographic projections of the first drain, the second drain, and the source on the substrate are all on a same side with respect to an orthographic projection of the gate on the substrate.

In the display panel of the present application, the sidewall, the first sidewall, and the second sidewall are located on a same plane.

In the display panel of the present application, the semiconductor layer includes a sloped part, a first horizontal part, and a second horizontal part; the sloped part is a portion of the semiconductor layer disposed on the sidewall of the bump structure, and the sloped part is located between the first horizontal part and the second horizontal part; the first horizontal part is located on one side of the substrate, and the second horizontal part is located on one side of the bump structure that is away from the substrate.

In the display panel of the present application, an angle between the first horizontal part and the sloped part ranges from 90° to 135°; and a thickness of each insulating layer ranges from 0.0071 to 1 micrometer.

The present application provides a display device, including a display panel, wherein the display panel includes: a substrate and a bump structure disposed on the substrate, the bump structure including at least two Ohmic contact layers stacked and at least one insulating layer, wherein one insulating layer is disposed between each adjacent pair of the Ohmic contact layers; and
a semiconductor layer, wherein at least part of the semiconductor layer is located on a sidewall of the bump structure, and the sidewall includes a first sidewall of the Ohmic contact layer and a second sidewall of the insulating layer disposed on a same side; the semiconductor layer includes at least one channel, and the channel is located on the second sidewall.

In the display device of the present application, the display panel further includes a gate disposed on one side of the semiconductor layer away from the bump structure, and an orthographic projection of the gate on the sidewall covers an orthographic projection of the channel on the sidewall.

In the display device of the present application, the at least two Ohmic contact layers include a first Ohmic contact layer and a second Ohmic contact layer sequentially stacked on the substrate, the at least one insulating layer includes a first insulating layer, and the first insulating layer is located between the first Ohmic contact layer and the second Ohmic contact layer; the at least one channel includes a first channel, and the first channel is disposed on the second sidewall of the first insulating layer.

In the display device of the present application, the at least two Ohmic contact layers further include a third Ohmic contact layer disposed on the second Ohmic contact layer, the at least one insulating layer further includes a second insulating layer, and the second insulating layer is located between the second Ohmic contact layer and the third Ohmic contact layer;
the at least one channel further includes a second channel, and the second channel is located on the second sidewall of the second insulating layer.

In the display device of the present application, the display panel further includes:
a gate insulation layer disposed between the gate and the semiconductor layer;
an interlayer dielectric layer disposed on one side of the gate away from the substrate, the interlayer dielectric layer covering the gate and the gate insulation layer;
a source-drain metal layer disposed on one side of the interlayer dielectric layer away from the substrate, the source-drain metal layer comprising a first drain, a source, and a second drain; and
a first contact hole, a second contact hole, and a third contact hole, penetrating through the interlayer dielectric layer and the gate insulation layer;
wherein the source is connected to the second Ohmic contact layer through the first contact hole, the first drain is connected to the first Ohmic contact layer through the second contact hole, and the second drain is connected to the third Ohmic contact layer through the third contact hole.

In the display device of the present application, the first Ohmic contact layer, the second Ohmic contact layer, and the third Ohmic contact layer are arranged in a stepped configuration;
the first Ohmic contact layer includes a first protruding part, and an orthographic projection of the second Ohmic contact layer on the substrate avoids overlapping with an orthographic projection of the first protruding part on the substrate; the second Ohmic contact layer includes a second protruding part, and an orthographic projection of the third Ohmic contact layer on the substrate avoids overlapping with an orthographic projection of the second protruding part on the substrate.

In the display device of the present application, the first drain and the second drain are located on two opposite sides of the source, respectively.

In the display device of the present application, orthographic projections of the first drain, the second drain, and the source on the substrate are all on a same side with respect to an orthographic projection of the gate on the substrate.

In the display device of the present application, the sidewall, the first sidewall, and the second sidewall are located on a same plane.

### BENEFICIAL EFFECTS

The beneficial effects of this application are: the display panel and device provided by the present application form a bump structure on the substrate by stacking Ohmic contact layers and insulating layers. The bump structure includes at least two Ohmic contact layers and at least one insulating layer, with one insulating layer positioned between two adjacent Ohmic contact layers. At least part of the semiconductor layer is located on a sidewall of the bump structure, contacting a first sidewall of the Ohmic contact layer. A channel of the semiconductor is located on a second sidewall of the insulating layer. By adjusting the length and the angle of the second sidewall, the channel length can be controlled. This not only reduces the channel length but also enables the stacking of multiple thin-film transistors in a thickness direction of the display panel, reducing the volume of thin devices, minimizing the device footprint, enhancing device integration, and facilitating the integration of IC circuits on the substrate.

### BRIEF DESCRIPTION OF DRAWINGS

To clearly illustrate the technical solutions in the embodiments of the present application, a brief introduction to the drawings used in the description of the examples follows. Evidently, the drawings described below are just some of the embodiments of this application. Without creative labor, those skilled in the art can derive other drawings based on these illustrations.

FIG. 1 shows a schematic plan view of a thin-film transistor according to one embodiment of the present application.

FIG. 2 is a schematic cross-sectional view along a B-B direction in FIG. 1.

FIG. 3 is a schematic cross-sectional view along an A-A direction in FIG. 1.

FIG. 4 is another schematic plan view of the thin-film transistor according to one embodiment of the present application.

FIG. 5 is a schematic cross-sectional view along a B-B direction in FIG. 4.

FIG. 6 is a schematic cross-sectional view along an A-A direction in FIG. 4.

FIGS. 7A to 7G show schematic views of the preparation process of a display panel according to one embodiment of the present application.

### DETAILED DESCRIPTION OF EMBODIMENTS

In conjunction with the accompanying drawings for the embodiments of the present application, the technical solutions within these embodiments are described clearly and completely. It is evident that the described embodiments represent only a portion of the embodiments, not all of them. All other embodiments derived by those skilled in the art, without engaging in creative labor, also fall within the scope of protection of this application. Moreover, it should be understood that the specific embodiments described here are intended solely for illustration and explanation of this application and are not meant to limit the scope of the application. In this application, unless otherwise specified, directional terms such as “up” and “down” typically refer to the orientation of the device in its actual use or operational state, as shown in the drawings; “inside” and “outside” refer to the contour of the device.

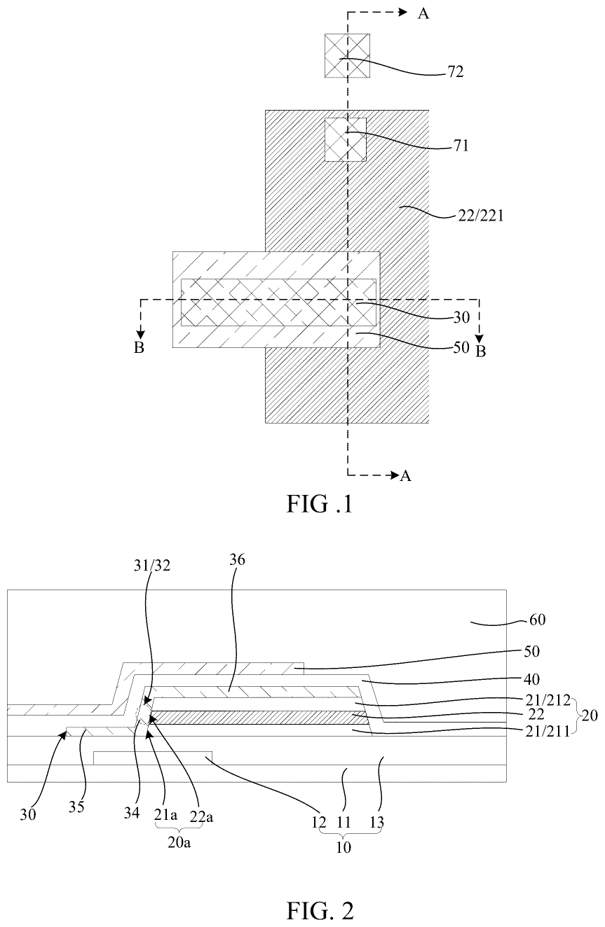

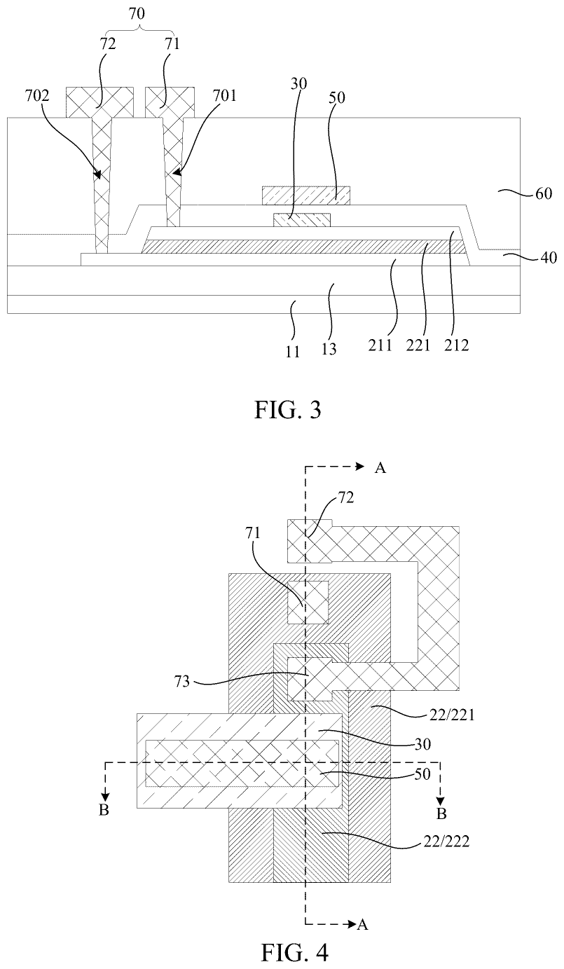

Please refer to FIGS. 1 to 3, where FIG. 1 presents a schematic plan view of a thin-film transistor according to one embodiment of the present application; FIG. 2 is a schematic cross-sectional view along a B-B direction in FIG. 1; FIG. 3 is a schematic cross-sectional view along an A-A direction in FIG. 1. The present embodiment provides a display panel, which includes a substrate 10 and thin-film transistors located on this substrate 10. The thin-film transistors can be used in various circuits within the display panel, such as pixel driving circuits, gate driving circuits, source driving circuits, timing controllers, and multiplexing circuits.

The display panel includes a substrate 10 and a bump structure 20 disposed on the substrate 10. The bump structure 20 includes at least two stacked Ohmic contact layers 21 and at least one insulating layer 22, with one insulating layer 22 positioned between the two adjacent Ohmic contact layers 21. The display panel also includes a semiconductor layer 30, with at least part of the semiconductor layer 30 located on a sidewall 20a of the bump structure 20. The sidewall 20a includes a first sidewall 21a of the Ohmic contact layer 21 and a second sidewall 22a of the insulating layer 22 disposed on the same side. The semiconductor layer 30 includes at least one channel 31. The channel 31 is located on the second sidewall 22a.

In conventional technology, active layers of thin-film transistors are prepared on the same plane, with multiple thin-film transistors laid out flat, resulting in a large footprint for the formed circuits. Additionally, due to the limitations of exposure and etching processes, the length of the channel 31 is generally more than 2 micrometers, which prevents further reduction in transistor size. In light of this, the display panel provided by this embodiment, by stacking the Ohmic contact layers 21 and the insulating layer 22 on the substrate 10 to form the bump structure 20, includes at least two stacked Ohmic contact layers 21 and at least one insulating layer 22 in the bump structure 20. One insulating layer 22 is positioned between two adjacent Ohmic contact layers 21, with at least part of the semiconductor layer 30 located on the sidewall 20a of the bump structure 20, where the semiconductor layer 30 contacts the first sidewall 21a of the Ohmic contact layer 21. The channel 31 of the semiconductor layer 30 is located on the second sidewall 22a of the insulating layer 22. By adjusting the length and angle of the second sidewall 22a, the length of the channel can be controlled. This not only reduces the length of the channel but also allows the stacking of multiple thin-film transistors in a thickness direction of the display panel, reducing the volume of thin devices, minimizing the device footprint, enhancing device integration, and facilitating the integration of IC circuits on the substrate 10.

In this embodiment, the substrate 10 includes a base 11, a light-shielding layer 12, and a buffer layer 13. The light-shielding layer 12 is positioned on the base 11, and the buffer layer 13 covers both the base 11 and the light-shielding layer 12.

The base 11 can be a glass substrate but is not limited to this; the base 11 can also be a flexible substrate 11. The light-shielding layer 12 is used to block ambient light from reaching the semiconductor layer 30. Specifically, it blocks ambient light from reaching the channel 31 in the semiconductor layer 30, to prevent external light from adversely affecting device performance. Optionally, the light-shielding layer 12 can be made of metal, which includes, but is not limited to, at least one of molybdenum, aluminum, titanium, copper, and silver; the light-shielding layer 12 can also be made from materials such as a black matrix. Optionally, the materials for the buffer layer 13 can include at least one of silicon nitride or silicon oxide. The thickness of the buffer layer 13 is greater than or equal to 2500 angstroms and is less than or equal to 3500 angstroms, such as 2500, 2800, 3000, 3200, or 3500 angstroms.

In the present embodiment, the material of the Ohmic contact layer 21 can be the same as the material of the semiconductor layer 30. The Ohmic contact layer 21 is doped with ions and consists of N-type heavily doped amorphous silicon. The Ohmic contact layer 21 can also be doped with impurity elements such as phosphorus or arsenic. The insulating layer 22 is used to separate the two adjacent Ohmic contact layers 21. Optionally, the insulating layer 22 can include at least one of an inorganic insulating layer or an organic insulating layer. The materials for the inorganic insulating layer include but are not limited to silicon oxide or silicon nitride, while the materials for the organic insulating layer include but are not limited to polyimide, polyacrylate, and organosilicon.

The semiconductor layer 30 covers at least the first sidewalls 21a of the at least two Ohmic contact layers 21 and the second sidewall 22a of at least one insulating layer 22. In the present embodiment, the first sidewalls 21a and the second sidewall 22a are located on the same side of the bump structure 20. The sidewall 20a, the first sidewalls 21a, and the second sidewall 22a are all in the same plane. This means that the angles formed by the sidewall 20a, the first sidewalls 21a, and the second sidewall 22a with respect to the substrate 10 are the same.

Specifically, the semiconductor layer 30 includes a sloped part 34, a first horizontal part 35, and a second horizontal part 36. The sloped part 34 is a portion of the semiconductor layer 30 located on the sidewall 20a of the bump structure 20, and the sloped part 34 is positioned between the first horizontal part 35 and the second horizontal part 36. The first horizontal part 35 is located on one side of the substrate 10, while the second horizontal part 36 is on one side of the bump structure 20 that is away from the substrate 10. One side of the sloped part 34 that is near the substrate 10 connects to the first horizontal part 35, and one side of the sloped part 34 that is away from the substrate 10 connects to the second horizontal part 36.

The reason for this configuration is as follows. On one hand, the material of the first horizontal part 35 is amorphous silicon, which, during the crystallization process to form the semiconductor layer 30, is more likely to form seed crystals at a corner between the buffer layer 13 and the sidewall 20a—specifically, at a corner between the first horizontal part 35 and the sloped part 34. As the seed crystals grow along the sidewall 20a and form a single crystal grain, in conjunction with the channel 31 on the sidewall 20a having a length of less than 1 micrometer, this provides the conditions for the channel 31 on the sidewall 20a to consist of a single crystal grain, meaning the channel 31 is composed of a single crystal without grain boundaries. This, in turn, creates conditions for forming semiconductor devices that include a single-crystal channel with high mobility. Compared to conventional thin-film transistor devices that have multiple grain boundaries, reducing the device size while significantly enhancing the mobility enhances the driving capability of the devices.

On the other hand, by extending the sloped part 34 to form the first horizontal part 35 and the second horizontal part 36, the adhesion between the semiconductor layer 30 and the film layer can be increased, enhancing the stability of the thin-film transistor devices. Additionally, the preparation of the small-sized semiconductor layer 30 can be achieved with the precision of existing photolithography equipment, without needing to change the manufacturing processes.

Specifically, in the present embodiment, the angle between the first horizontal part 35 and the sloped part 34 ranges from 90° to 135°. This angle θ is also the angle between the sidewall 20a and the substrate 10, as well as the angle formed by the first sidewall 21a and the second sidewall 22a with respect to the substrate 10. In this embodiment, the thickness of each insulating layer 22 ranges from 0.0071 to 1 micrometer. By controlling the aforementioned angles and thicknesses, the length of the channel 31 can be controlled to be less than 1 micrometer.

The display panel further includes a gate 50. The gate 50 is located on one side of the semiconductor layer 30 away from the bump structure 20. An orthographic projection of the gate 50 on the sidewall 20a covers an orthographic projection of the channel 31 on the same sidewall 20a, facilitating control over the position and length of the channel 31. Optionally, the material for the gate 50 can be selected from at least one of molybdenum, aluminum, titanium, copper, and silver.

In one embodiment, as further illustrated in FIGS. 1 to 3, the bump structure 20 consists of two Ohmic contact layers 21 and one insulating layer 22, forming a device that includes a thin-film transistor. Specifically, the at least two Ohmic contact layers 21 include a first Ohmic contact layer 211 and a second Ohmic contact layer 212 sequentially stacked on the substrate 10. The at least one insulating layer 22 includes a first insulating layer 221, which is positioned between the first Ohmic contact layer 211 and the second Ohmic contact layer 212. The at least one channel includes a first channel 32, which is located on the second sidewall 22a of the first insulating layer 221.

It can be understood that, in this embodiment, the semiconductor layer 30 is in contact with the first Ohmic contact layer 211 and the second Ohmic contact layer 212. A portion of the semiconductor layer 30 located between the first Ohmic contact layer 211 and the second Ohmic contact layer 212 forms the first channel 32 of the thin-film transistor. Specifically, the length of the first channel 32 can be determined by the length and angle of the second sidewall 22a of the first insulating layer 221 situated between the first Ohmic contact layer 211 and the second Ohmic contact layer 212. By adjusting the length and angle of the second sidewall 22a of the first insulating layer 211, the lengths of the first channel 32 and a second channel 33 can be controlled, easily maintaining the length of the first channel 32 under one micrometer with existing technologies.

Furthermore, in other embodiments, two thin-film transistors can be stacked, but the present application is not limited in this regard. Three, four, or more thin-film transistors can also be stacked. This embodiment specifically describes the stacking of two thin-film transistors as an example for illustrative purposes.

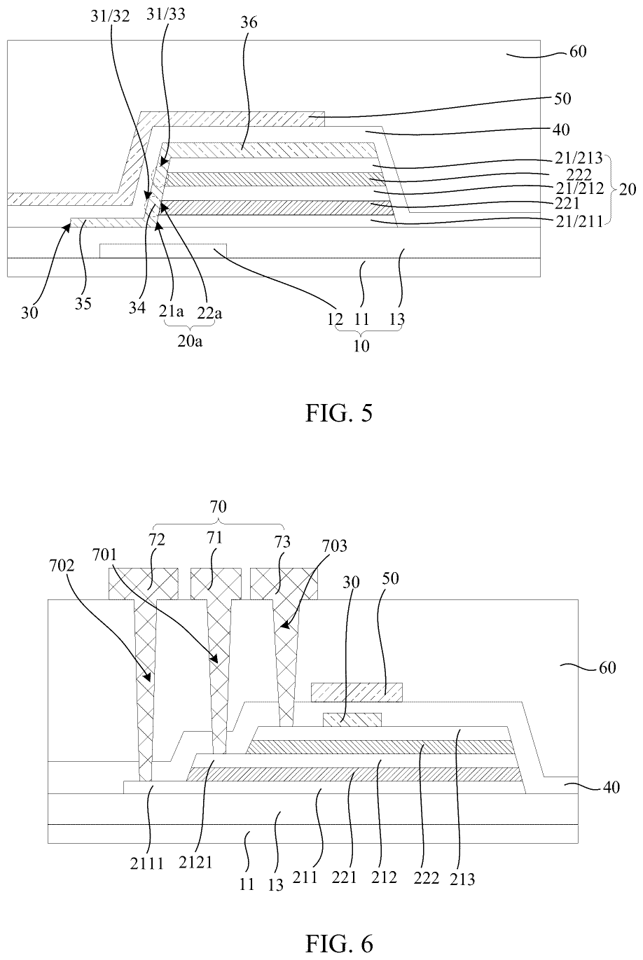

Please refer to FIGS. 4 to 6. FIG. 4 presents another schematic plan view of a thin-film transistor according to one embodiment of the present application; FIG. 5 is a cross-sectional view along a B-B direction in FIG. 4; FIG. 6 is a cross-sectional view along an A-A direction in FIG. 4. The difference between FIGS. 4 to 6 and FIGS. 1 to 3 is that the at least two Ohmic contact layers 21 include a third Ohmic contact layer 213 disposed over the second Ohmic contact layer 212, and the at least one insulating layer further includes a second insulating layer 222. The second insulating layer 222 is located between the second Ohmic contact layer 212 and the third Ohmic contact layer 213. The at least one channel 31 further includes a second channel 33. The second channel 33 is located on the second sidewall 22a of the second insulating layer 222.

In this embodiment, the bump structure 20 consists of three Ohmic contact layers and three insulating layers. Specifically, the bump structure 20 includes the first Ohmic contact layer 211, the first insulating layer 221, the second Ohmic contact layer 212, the second insulating layer 222, and the third Ohmic contact layer 213, sequentially stacked on the substrate 10. The device in this embodiment includes two thin-film transistors disposed in the thickness direction of the display panel, with each of the two thin-film transistors featuring one channel 31.

It is understood that in this embodiment, the semiconductor layer 30 is in contact with the first Ohmic contact layer 211, the second Ohmic contact layer 212, and the third Ohmic contact layer 213. A portion of the semiconductor layer 30 situated between the first Ohmic contact layer 211 and the second Ohmic contact layer 212 forms the first channel 32 of one thin-film transistor. Similarly, a portion of the semiconductor layer 30 located between the second Ohmic contact layer 212 and the third Ohmic contact layer 213 forms the second channel 33 of another thin-film transistor. The length of the first channel 32 can be determined by the length and angle of the second sidewall 22a of the first insulating layer 221 which is between the first Ohmic contact layers 211 and the second Ohmic contact layer 212. Likewise, the length of the second channel 33 can be determined by the length and angle of the second sidewall 22a of the second insulating layer 222 which is between the second Ohmic contact layers 212 and the third Ohmic contact layer 213. Therefore, in this embodiment, by simply adjusting the lengths and angles of the second sidewalls 22a of the first insulating layer 221 and the second insulating layer 222, the lengths of the first channel 32 and the second channel 33 can be controlled, making it easy to keep the lengths of both the first and second channels 32 and 33 under 1 micrometer with existing technologies.

The display panel further includes a gate insulation layer 40, an interlayer dielectric layer 60, a source-drain metal layer 70, a first contact hole 701, a second contact hole 702, and a third contact hole 703. The gate insulation layer 40 is disposed between the gate 50 and the semiconductor layer 30. The interlayer dielectric layer 60 is disposed on one side of the gate insulation layer 40 that is away from the substrate 10, covering both the gate 50 and the gate insulation layer 40. The source-drain metal layer 70 is disposed on one side of the interlayer dielectric layer 60 that is away from the substrate 10, and includes a first drain 72, a source 71, and a second drain 73. The first contact hole 701, the second contact hole 702, and the third contact hole 703 penetrate through the interlayer dielectric layer 60 and the gate insulation layer 40.

To achieve parallel connection of two thin-film transistors, in this embodiment, the two transistors share the source 71. Since the second Ohmic contact layer 212 is disposed between the first Ohmic contact layer 211 and the second Ohmic contact layer 212, for ease of wiring, the source 71 is connected to the second Ohmic contact layer 212. The drains of the two transistors (the first drain 72 and the second drain 73) are connected respectively to the first Ohmic contact layer 211 and the second Ohmic contact layer 212. Specifically, the source 71 is connected to the second Ohmic contact layer 212 through the first contact hole 701, the first drain 72 is connected to the first Ohmic contact layer 211 through the second contact hole 702, and the second drain 73 is connected to the third Ohmic contact layer 213 through the third contact hole 703.

It is understood that in this embodiment, by connecting two stacked thin-film transistors in parallel—essentially setting the two channels 31 (the first channel 32 and the second channel 33) in parallel—the actual width of the device in this embodiment is the sum of the widths of the first channel 32 and the second channel 33. This configuration allows for an increase in device width within a limited space, which is beneficial for increasing the on-state current and enhancing the driving capability of the device. Additionally, stacking two thin-film transistors in the thickness direction of the display panel helps to reduce the volume and the occupying area of the device, thereby enhancing the integration of the device.

It should be noted that, to enable the source 71, the first drain 72, and the second drain 73 to connect through the contact holes with the corresponding Ohmic contact layers 21, the multiple Ohmic contact layers 21 need to be adapted. Specifically, in this embodiment, the first Ohmic contact layer 211, the second Ohmic contact layer 212, and the third Ohmic contact layer 213 are designed in a stepped configuration; the first Ohmic contact layer 211 includes a first protruding part 2111, and an orthographic projection of the second Ohmic contact layer 212 on the substrate 10 does not overlap with an orthographic projection of the first protruding part 2111 on the substrate 10. The second Ohmic contact layer 212 includes a second protruding part 2121, and an orthographic projection of the third Ohmic contact layer 213 on the substrate 10 does not overlap with an orthographic projection of the second protruding part 2121. By making the first Ohmic contact layer 211 protrude beyond the second and third Ohmic contact layers 212 and 213, the present application prevents the first drain 72 from passing through the second and third Ohmic contact layers 212 and 213; and by making the second Ohmic contact layer 212 protrude beyond the third Ohmic contact layer 213, the present application prevents the source 71 from passing through the third Ohmic contact layer 213.

In this embodiment, the first drain 72 and the second drain 73 are located on two opposite sides of the source 71 to facilitate the wiring design.

In the present embodiment, orthographic projections of the first drain 72, the second drain 73, and the source 71 on the substrate 10 are all located on the same side with respect to an orthographic projection of the gate 50 on the substrate 10. This positioning ensures that the formed channels are located on the second sidewall 22a.

It should be noted that the above embodiments involve configurations with one thin-film transistor and configurations with two stacked thin-film transistors. Embodiments involving the stacking of more thin-film transistors are similar to the above-mentioned embodiments and can refer to the descriptions above.

Please refer to the drawings. This embodiment also provides a manufacturing method, including the following steps:
S10: providing a substrate 10.

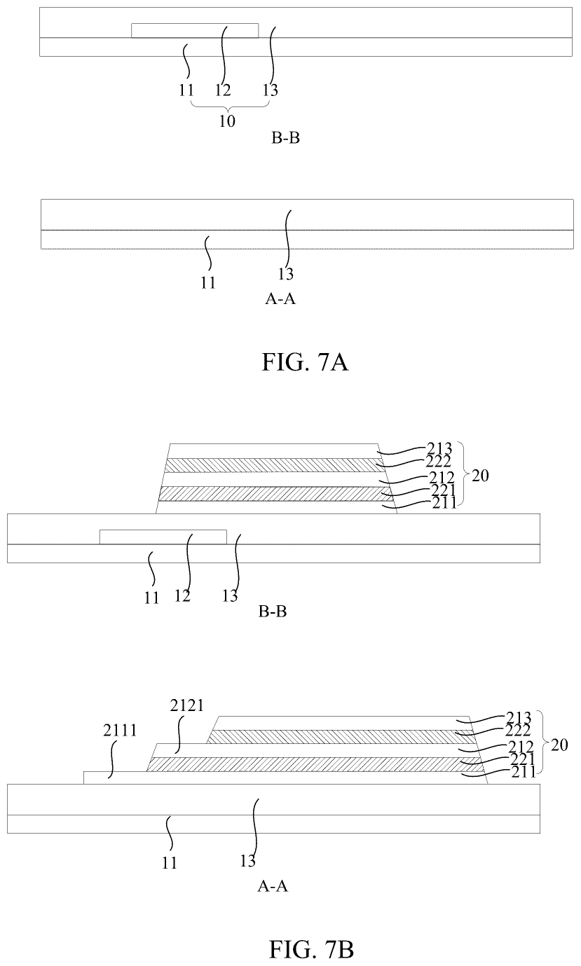

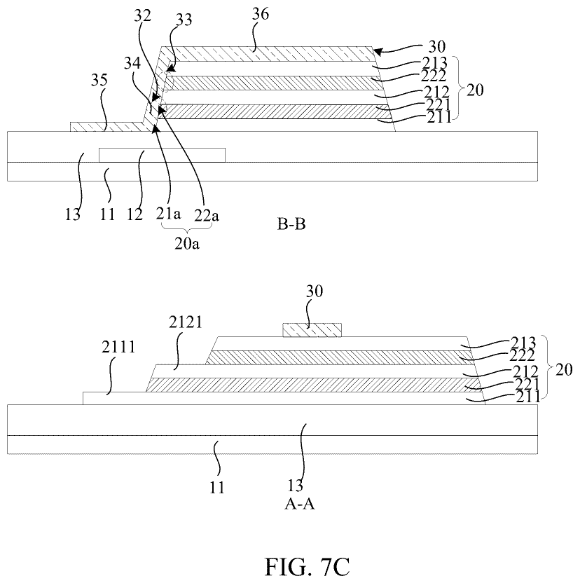

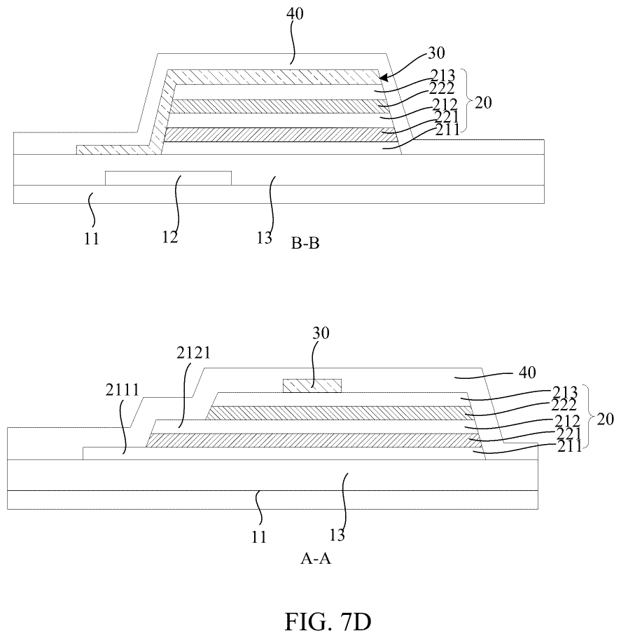

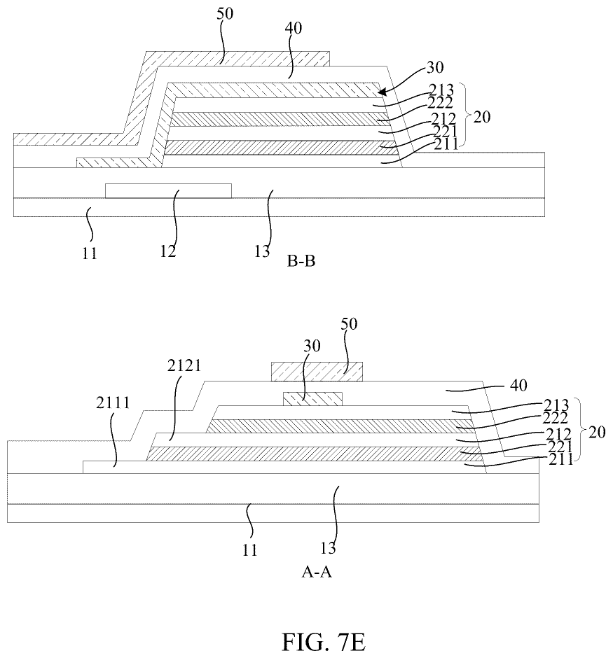

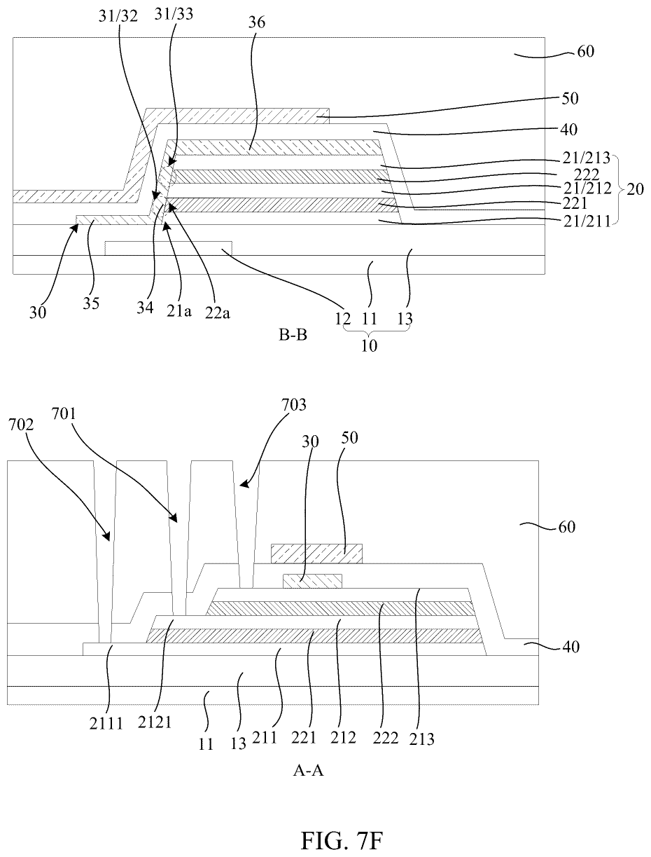

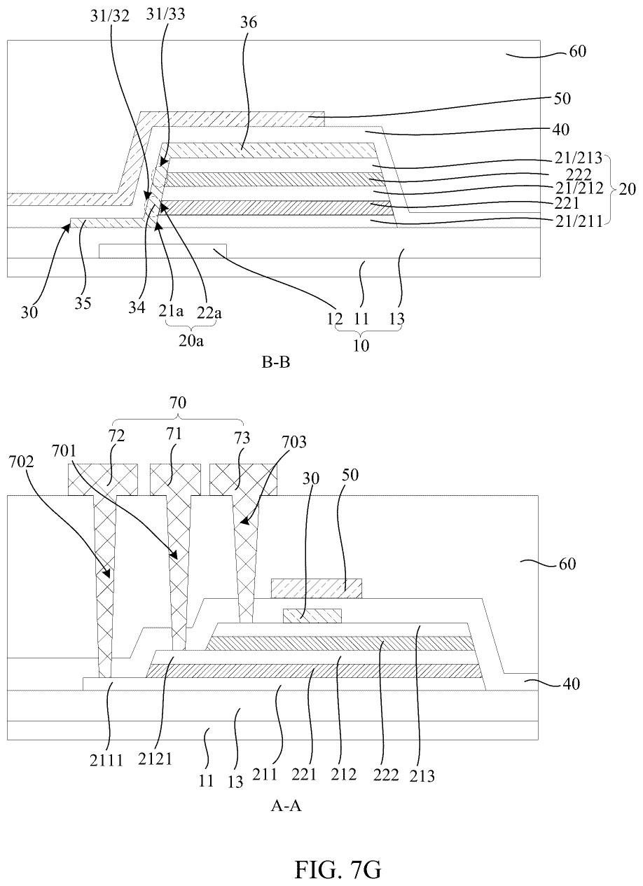

Specifically, as shown in FIG. 7A, step S10 includes the following sub-steps: providing a base 11; forming a light-shielding layer 12 on the base 11; and forming a buffer layer 13 that covers both the base 11 and the light-shielding layer 12.
S20: forming a bump structure 20 on the substrate 10, where the bump structure 20 includes at least two Ohmic contact layers in a stacked relationship and at least one insulating layer 22, with one insulating layer 22 positioned between two adjacent Ohmic contact layers.

Specifically, taking the configuration with two thin-film transistors as an example, as shown in FIG. 7B, materials are sequentially stacked on the buffer layer 13 in the following order: the material for the first Ohmic contact layer 211, the material for the first insulating layer 221, the material for the second Ohmic contact layer 212, the material for the second insulating layer 222, the material for the third Ohmic contact layer 213, the material for the third insulating layer, and the material for the fourth Ohmic contact layer. Subsequently, etching at various depths is performed to form the first Ohmic contact layer 211, the first insulating layer 221, the second Ohmic contact layer 212, the second insulating layer 222, and the third Ohmic contact layer 213. It should be noted that the etching processes at different depths can be carried out using a single grayscale mask or multiple photomasks; this is not limited here.
S30: forming a semiconductor layer 30 that is at least partially disposed on a sidewall 20a of the bump structure 20, where the sidewall 20a includes a first sidewall 21a of the Ohmic contact layers 21 and a second sidewall 22a of the insulating layer 22 disposed on the same side.

Specifically, as shown in FIG. 7C, amorphous silicon material is deposited on the third Ohmic contact layer 213 and subjected to crystallization treatment. The amorphous silicon material is then etched to form the pattern of the semiconductor layer 30. The crystallization of the amorphous silicon material can be carried out using an excimer laser annealing process. Due to the limited energy of the excimer laser annealing process, which is entirely absorbed by the amorphous silicon, the Ohmic contact layers 21 can still maintain their amorphous silicon structure during the crystallization of the amorphous silicon layer. The crystallization of the amorphous silicon material can also be performed after an oxidation process; there are no restrictions here.

The manufacturing method further includes: S40: forming a gate insulation layer 40 that covers the substrate 10 and the bump structure 20, as shown in FIG. 7D; S50: forming a gate 50 on one side of the gate insulation layer 40 that is away from the bump structure 20, as shown in FIG. 7E; S60: forming an interlayer dielectric layer 60 that covers both the gate 50 and the gate insulation layer 40, as shown in FIG. 7F; S70: forming a first contact hole 701, a second contact hole 702, and a third contact hole 703 that penetrate through the interlayer dielectric layer 60 and the gate insulation layer 40, as shown in FIG. 7F; S80: forming a source-drain metal layer 70 on one side of the interlayer dielectric layer 60 that is away from the substrate 10, as shown in FIG. 7G, where the source-drain metal layer 70 includes a first drain 72, a source 71, and a second drain 73. The first drain 72 is connected through the first contact hole 701 to the first Ohmic contact layer 211, the source 71 is connected through the second contact hole 702 to the second Ohmic contact layer 212, and the second drain 73 is connected through the third contact hole 703 to the third Ohmic contact layer 213.

The present application further provides a display device that includes the display panel described in the aforementioned embodiment. The display device includes, but is not limited to, electronic paper, mobile phones, tablet computers, televisions, monitors, laptops, digital photo frames, GPS, etc.

Beneficial Effects: The display panel and display device provided by the embodiments of the present application, by stacking Ohmic contact layers and insulating layers on the substrate to form a bump structure, which includes at least two stacked Ohmic contact layers and at least one insulating layer, with one insulating layer positioned between two adjacent Ohmic contact layers, offer advantages. At least part of the semiconductor layer is located on the sidewall of the bump structure. The semiconductor layer contacts the first sidewall of the Ohmic contact layer. The channel of the semiconductor is located on the second sidewall of the insulating layer. By adjusting the length and angle of the second sidewall, the channel length can be controlled. This not only reduces the channel length but also enables the stacking of multiple thin-film transistors in the thickness direction of the display panel, reducing the volume of thin devices, decreasing the device footprint, enhancing device integration, and facilitating the integration of IC circuits on the substrate.

In summary, although the present application has been disclosed above in preferred embodiments, these preferred embodiments are not intended to limit the scope of this application. Those skilled in the art may make various modifications and enhancements without departing from the spirit and scope of this application. Therefore, the scope of protection of this application is defined by the scope of the claims.

What is claimed is:

1. A display panel, comprising:
a substrate and a bump structure disposed on the substrate, the bump structure comprising at least two Ohmic contact layers stacked and at least one insulating layer, wherein one insulating layer is disposed between each adjacent pair of the Ohmic contact layers; and
a semiconductor layer, wherein at least part of the semiconductor layer is located on a sidewall of the bump structure, and the sidewall comprises a first sidewall of the Ohmic contact layer and a second sidewall of the insulating layer disposed on a same side; the semiconductor layer comprises at least one channel, and the channel is located on the second sidewall.

2. The display panel according to claim 1, further comprising a gate disposed on one side of the semiconductor layer away from the bump structure, wherein an orthographic projection of the gate on the sidewall covers an orthographic projection of the channel on the sidewall.

3. The display panel according to claim 2, wherein the at least two Ohmic contact layers comprise a first Ohmic contact layer and a second Ohmic contact layer sequentially stacked on the substrate, the at least one insulating layer comprises a first insulating layer, and the first insulating layer is located between the first Ohmic contact layer and the second Ohmic contact layer; the at least one channel comprises a first channel, and the first channel is disposed on the second sidewall of the first insulating layer.

4. The display panel according to claim 3, wherein the at least two Ohmic contact layers further comprise a third Ohmic contact layer disposed on the second Ohmic contact layer, the at least one insulating layer further comprises a second insulating layer, and the second insulating layer is located between the second Ohmic contact layer and the third Ohmic contact layer; the at least one channel further comprises a second channel, and the second channel is located on the second sidewall of the second insulating layer.

5. The display panel according to claim 4, further comprising:
a gate insulation layer disposed between the gate and the semiconductor layer; an interlayer dielectric layer disposed on one side of the gate away from the substrate, the interlayer dielectric layer covering the gate and the gate insulation layer;
a source-drain metal layer disposed on one side of the interlayer dielectric layer away from the substrate, the source-drain metal layer comprising a first drain, a source, and a second drain; and
a first contact hole, a second contact hole, and a third contact hole, penetrating through the interlayer dielectric layer and the gate insulation layer;
wherein the source is connected to the second Ohmic contact layer through the first contact hole, the first drain is connected to the first Ohmic contact layer through the second contact hole, and the second drain is connected to the third Ohmic contact layer through the third contact hole.

6. The display panel according to claim 5, wherein the first Ohmic contact layer, the second Ohmic contact layer, and the third Ohmic contact layer are arranged in a stepped configuration;
the first Ohmic contact layer comprises a first protruding part, and an orthographic projection of the second Ohmic contact layer on the substrate avoids overlapping with an orthographic projection of the first protruding part on the substrate; the second Ohmic contact layer comprises a second protruding part, and an orthographic projection of the third Ohmic contact layer on the substrate avoids overlapping with an orthographic projection of the second protruding part on the substrate.

7. The display panel according to claim 6, wherein the first drain and the second drain are located on two opposite sides of the source, respectively.

8. The display panel according to claim 7, wherein orthographic projections of the first drain, the second drain, and the source on the substrate are all on a same side with respect to an orthographic projection of the gate on the substrate.

9. The display panel according to claim 1, wherein the sidewall, the first sidewall, and the second sidewall are located on a same plane.

10. The display panel according to claim 9, wherein the semiconductor layer comprises a sloped part, a first horizontal part, and a second horizontal part; the sloped part is a portion of the semiconductor layer disposed on the sidewall of the bump structure, and the sloped part is located between the first horizontal part and the second horizontal part; the first horizontal part is located on one side of the substrate, and the second horizontal part is located on one side of the bump structure that is away from the substrate.

11. The display panel according to claim 10, wherein an angle between the first horizontal part and the sloped part ranges from 90° to 135°; and a thickness of each insulating layer ranges from 0.0071 to 1 micrometer.

12. A display device, comprising a display panel, wherein the display panel comprises:
a substrate and a bump structure disposed on the substrate, the bump structure comprising at least two Ohmic contact layers stacked and at least one insulating layer, wherein one insulating layer is disposed between each adjacent pair of the Ohmic contact layers; and
a semiconductor layer, wherein at least part of the semiconductor layer is located on a sidewall of the bump structure, and the sidewall comprises a first sidewall of the Ohmic contact layer and a second sidewall of the insulating layer disposed on a same side; the semiconductor layer comprises at least one channel, and the channel is located on the second sidewall.

13. The display device according to claim 12, wherein the display panel further comprises a gate disposed on one side of the semiconductor layer away from the bump structure, and an orthographic projection of the gate on the sidewall covers an orthographic projection of the channel on the sidewall.

14. The display device according to claim 13, wherein the at least two Ohmic contact layers comprise a first Ohmic contact layer and a second Ohmic contact layer sequentially stacked on the substrate, the at least one insulating layer comprises a first insulating layer, and the first insulating layer is located between the first Ohmic contact layer and the second Ohmic contact layer;
the at least one channel comprises a first channel, and the first channel is disposed on the second sidewall of the first insulating layer.

15. The display device according to claim 14, wherein the at least two Ohmic contact layers further comprise a third Ohmic contact layer disposed on the second Ohmic contact layer, the at least one insulating layer further comprises a second insulating layer, and the second insulating layer is located between the second Ohmic contact layer and the third Ohmic contact layer;
the at least one channel further comprises a second channel, and the second channel is located on the second sidewall of the second insulating layer.

16. The display device according to claim 15, wherein the display panel further comprises:
a gate insulation layer disposed between the gate and the semiconductor layer;
an interlayer dielectric layer disposed on one side of the gate away from the substrate, the interlayer dielectric layer covering the gate and the gate insulation layer;
a source-drain metal layer disposed on one side of the interlayer dielectric layer away from the substrate, the source-drain metal layer comprising a first drain, a source, and a second drain; and
a first contact hole, a second contact hole, and a third contact hole, penetrating through the interlayer dielectric layer and the gate insulation layer;
wherein the source is connected to the second Ohmic contact layer through the first contact hole, the first drain is connected to the first Ohmic contact layer through the second contact hole, and the second drain is connected to the third Ohmic contact layer through the third contact hole.

17. The display device according to claim 16, wherein the first Ohmic contact layer, the second Ohmic contact layer, and the third Ohmic contact layer are arranged in a stepped configuration;
the first Ohmic contact layer comprises a first protruding part, and an orthographic projection of the second Ohmic contact layer on the substrate avoids overlapping with an orthographic projection of the first protruding part on the substrate; the second Ohmic contact layer comprises a second protruding part, and an orthographic projection of the third Ohmic contact layer on the substrate avoids overlapping with an orthographic projection of the second protruding part on the substrate.

18. The display device according to claim 17, wherein the first drain and the second drain are located on two opposite sides of the source, respectively.

19. The display device according to claim 18, wherein orthographic projections of the first drain, the second drain, and the source on the substrate are all on a same side with respect to an orthographic projection of the gate on the substrate.

20. The display device according to claim 12, wherein the sidewall, the first sidewall, and the second sidewall are located on a same plane.
